(19) United States
(12) Patent Application Publication
(10) Pub. No.: US 2003/0218868 A1
(43) Pub. Date: Nov. 27, 2003

(54) Multi-chip module

(76) Inventor: Wen-Wen Chiu, Hsin Chu City (TW)

Correspondence Address: BROWDY AND NEIMARK, P.L.L.C., 624 NINTH STREET, NW, SUITE 300, WASHINGTON, DC, 20001-5303, US

(21) Appl. No.: 10/153,904

(22) Filed: May 24, 2002

(51) Int. Cl. H05K 7/00

(52) U.S. Cl. 361/729

(57) ABSTRACT

The present invention is to provide a multi-chip module including a substrate, at least a chip, a plurality of bonding wires, and a cover body. The substrate has a top surface, a bottom surface, and at least a receiving chamber recessed inward from the top surface toward the bottom surface of the substrate. The chip is fixedly received in the receiving chamber and provided with a plurality of bonding pads. Each of the bonding wires has one end electrically connected to one of the bonding pads of the chip and the other end substantially horizontally electrically connected to a conductive pattern of the substrate. The cover body is fixedly mounted on the top surface of the substrate for covering the receiving chamber and isolating the chip from the outside, whereby the cover body is extremely adjacently mounted on the top surface of the substrate to effectively reduce the overall thickness of the module.

### FIELD OF THE INVENTION

The present invention relates to an integrated circuit (IC) chip package, and more particularly to a multi-chip module package.

### BACKGROUND OF THE INVENTION

According to prior art, a conventional circuit module is made by a method of packaging each single chip and then electrically connecting and assembling all packaged chips to a circuit board. Because the foregoing method includes two different manufacturing processes of the chip packaging and assembly, some practitioners make an improved module by the method of electrically connecting the chip to the circuit board directly and then encapsulating the chip by dielectric thermosetting resin to save time of the manufacturing process.

FIG. 1 shows a prior art multi-chip module 10 obtained by the above-described process. The multi-chip module 10 has a plurality of chips 12 mounted on a top side of a circuit board 14 and electrically connected to the circuit board 14 by bonding wires 16. Then, these chips 12 are encapsulated by dielectric thermosetting resin 18, such as epoxy resin.

The foregoing prior art includes some drawbacks. Firstly, the chips and portions of the circuit board are encapsulated by the dielectric resin, so it's quite difficult to remove and replace the damaged chips from a circuit board once some chips are malfunctioned or damaged. Secondly, the chips and the encapsulants are exposed outside the circuit board, so the thickness of overall module increases and it does not meet the present design requirement of electronic products as being light, thin, short, and small. Thirdly, the upper portion of overall multi-chip module 10 is not smooth due to the existence of the chips and encapsulant on the top surface of the circuit board, such that the chips proposed to be attached on a bottom side of the circuit board can not undergo wire-bonding process because the rough non-smooth upper surface of the circuit board can not serve as a flat supporting surface for the wire bonding when the circuit board is upside down. In other words, it is difficult to mount chips on the bottom surface of the circuit board in case the upper surface is mounted with the chips and encapsulated with the encapsulants. Therefore, it is inefficient at space utilization since the position of the module for receiving the chips is confined on one surface only.

### SUMMARY OF THE INVENTION

The primary objective of the present invention is to provide a multi-chip module capable of replacing and repairing the chip easily.

It is another objective of the present invention to provide a multi-chip module, which has lesser thickness overall.

It is still another objective of the present invention to provide a multi-chip module, which can assemble chips easily on a top side and a bottom side of a circuit board such that it is efficient at pace utilization.

In keeping with the principle of the present invention, the foregoing objectives of the present invention are attained by the multi-chip module comprises a substrate, which has a top surface, a bottom surface, and at least one receiving chamber recessed inward on the top surface, at least a chip fixedly mounted in the receiving chamber and having a plurality of bonding pads; a plurality of bonding wires, each one of the bonding wires having one end electrically connected to one of the bonding pads of the chip, and the other end substantially approximately horizontally electrically connected to a conductive pattern of the substrate, a cover body fixedly mounted on the top surface of the substrate for covering the receiving chamber.

According to a preferred embodiment of the present invention, the cover body is fixedly fastened over the top surface of the substrate by means of adhesives. In another preferred embodiment of the present invention, the cover body is mounted on the substrate by means of screws. Therefore, the cover body provided by the present invention is easy to remove such that it is easy to check and repair the chip.

Moreover, the substrate or the cover body in accordance with the present invention is disposed with a predetermined conductive pattern, on which a plurality of protrusions are disposed, whereby the ends of the substantially horizontal bonding wires can be respectively connected to the protrusions so as to insure the stability of the connection between the bonding wires and the conductive pattern.

Further, when the present invention is put into practice, a bottom surface of the cover body can be lowered to contact bonding points of all bonding wires and the conductive pattern or protrusions, thereby the cover body can almost touch the top surface of the substrate and be mounted over the top surface of the substrate, such that the overall thickness of the module can be effectively reduced.

Furthermore, the cover body mounted over the top surface of the substrate can be designed as a smooth plate such that it can serve as a smooth supporting surface, enabling the wire bonding process while installing the chips on the bottom surface of the substrate. In other words, it's easy to install the chips both on the top and bottom surfaces of the substrate, and then space can be utilized efficiently.

The substantial structure and features of the present invention will be more readily understood upon a thoughtful deliberation of the following detailed description of preferred embodiments of the present invention with reference to the accompanying drawings.

### BRIEF DESCRIPTION OF THE DRAWINGS

FIG. 1 is a cross-sectional view of a prior art multi-chip module;

FIG. 2 is a cross-sectional view of a first preferred embodiment in accordance with the present invention;

FIG. 3 is a partial enlarged view of FIG. 2;

FIG. 4 is a cross-sectional view of a second preferred embodiment in accordance with the present invention;

FIG. 5 is a partial enlarged view of FIG. 4;

FIG. 6 is a cross-sectional view of a third preferred embodiment in accordance with the present invention;

FIG. 7 is a cross-sectional view of a fourth preferred embodiment in accordance with the present invention;

FIG. 8 is a cross-sectional view of a fifth preferred embodiment in accordance with the present invention;

FIG. 9 is a schematic view showing the multi-chip module as shown in FIG. 8 is assembled onto an external circuit board;

FIG. 10 is a cross-sectional view of a sixth preferred embodiment in accordance with the present invention;

FIG. 11 is a cross-sectional view of a seventh preferred embodiment in accordance with the present invention;

FIG. 12 is a cross-sectional view of an eighth preferred embodiment in accordance with the present invention; and

FIG. 13 is a cross-sectional view of a ninth preferred embodiment in accordance with the present invention.

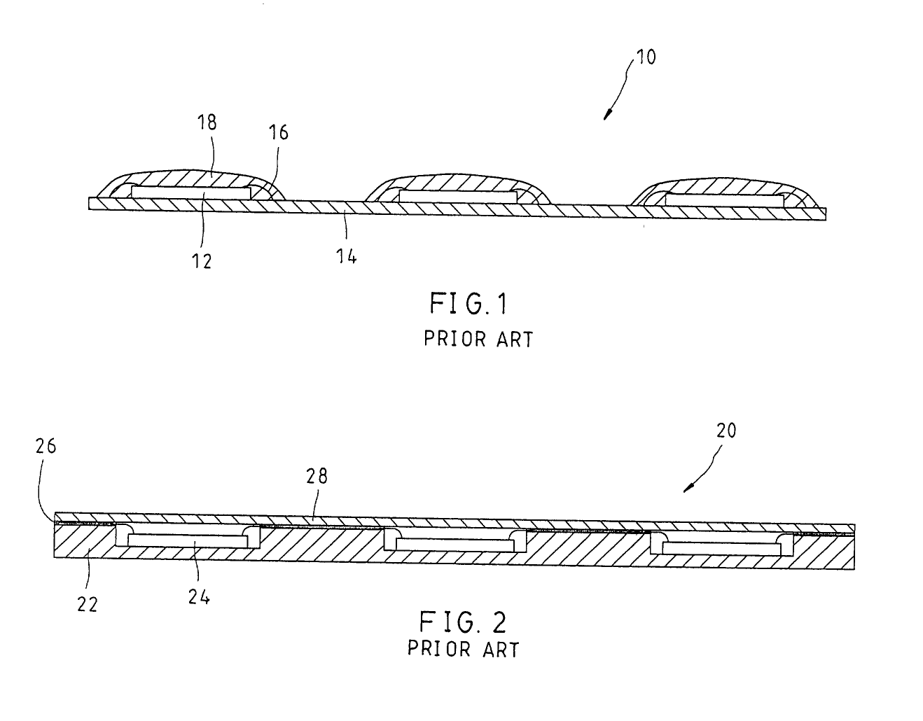

### DETAILED DESCRIPTION OF THE INVENTION

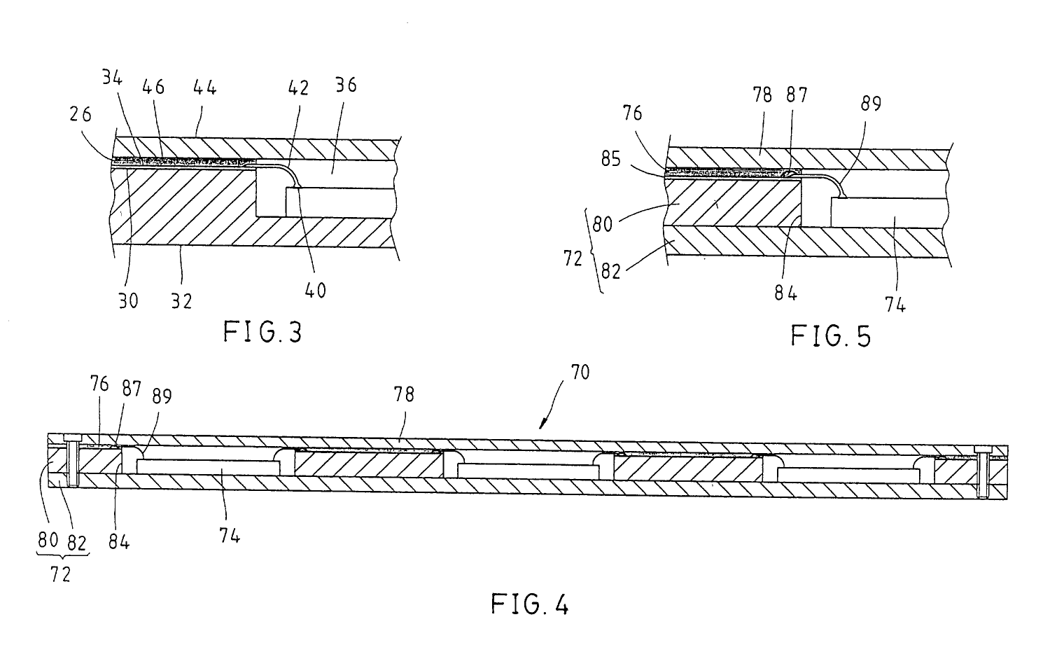

Referring to FIGS. 2-3, there depict a first preferred embodiment of a multi-chip module 20 of the present invention. The module 20 primarily comprises a substrate 22, a plurality of chips 24, an adhesive 26, and a cover body 28.

The substrate 22, which can be a single-layer or multi-layer circuit board made of thermosetting plastics, glass fiber reinforced resin, ceramic materials, etc, has a top surface 30, a bottom surface 32, a predetermined conductive pattern 34 disposed on the top surface 30, and a plurality of receiving chambers 36 recessed inward from the top surface 30 toward the bottom surface 32. The conductive pattern 34 can be provided for being electrically connected with electronic components (not shown) with predetermined numbers and functions.

Each one of the chips 24 is fixedly adhered to the bottom side of the receiving chamber 36 through an adhesive material, such as epoxy resin, silicon resin, adhesive tape, etc. The chip 24 is provided at the top surface thereof with a plurality of bonding pads 40 which are electrically respectively connected to the conductive pattern 34 of the substrate 22 through bonding wires 42 by the technology of wire bonding. In the process of wire bonding, each one of the bonding wires 42 has one end vertically fixedly bonded to one of the bonding pads 40 (first bonding point), and the other end pulled upward and straight to be bonded to a predetermined connecting point (second bonding point) of the conductive pattern 34 of the top surface of the substrate 22. The bonding wires 42 are substantially horizontally fixedly bonded with the conductive pattern 34 such that space of the top surface 30 of the substrate 22 reserved for the bonding wires 42 can be dramatically reduced.

The adhesive 26, which is a material selected from the group consisting of silicone resin, epoxy resin, acrylic resin, and polyamide resin, is coated on the top surface 30 of the substrate 22 and covers the bonding points where the bonding wires 42 are bonded to the conductive pattern 34. Basically, the adhesive 26 is in a sticky stage in the initial process of coating, and then it will cure after drying.

The cover body 28, which is a planar plate made of a transparent or opaque plastics, glasses or other materials, or can be a single-layer circuit board or a multi-layer circuit board, has a top surface 44 and a bottom surface 46. The bottom surface 46 of the cover body is partially adhered to the adhesive 26 such that the cover body 28 can be mounted over the top surface 30 of the substrate 22 to cover all receiving chambers 36, and the chips 24 are isolated from the outside.

Moreover, it is to be recited herewith that the cover body 28 of the multi-chip module 20 of the present invention can be fixedly mounted on the top surface 30 of the substrate 22 by several screws, as shown in FIG. 4, so that it's convenient to remove the cover body 28 to check and repair the chips.

Furthermore, the bonding wires 42 of the present invention are substantially horizontally electrically connected to the conductive pattern of the substrate, so that the space of the top surface is not necessarily previously reserved for receiving the bonding wires. As a result, when the cover body 28 is mounted on the substrate, the bottom surface 46 can be lowered to contact bonding points where all bonding wires 42 are bonded to the conductive pattern 34, whereby the thickness of overall module can be reduced effectively.

As shown in FIGS. 4-5, a multi-chip module 70 provided by a second preferred embodiment of the present invention primarily comprises a substrate 72, a plurality of chips 74, an adhesive 76, and a cover body 78. The difference between the second and the first preferred embodiments is described hereunder.

The substrate 72 is composed of an upside plate 80 and a downside plate 82. The upside plate 80, on which the conductive pattern is disposed, has a plurality of holes 84 running through its top and bottom surfaces. The downside plate 82 has a top surface attached to the bottom surface of the upside plate 80, whereby the receiving chambers 36 are formed by all holes 84 and the downside plate 82.

Moreover, the conductive pattern 85 of the substrate 72 is electrically connected with a plurality of protrusions 87, which are made of a metallic material by welding, chemical accumulation, or other ways and extrude a predetermined height out of the top surface of the substrate 72. All of the protrusions 87 electrically connected to the conductive pattern 85 are located around the periphery of an opening of the receiving chamber and are fixedly connected with horizontal ends of the bonding wires 89. Accordingly, the bonding wires 89 are bonded to the cubic protrusions 87 extruding a predetermined height out of the conductive pattern, such that the connection is reinforced to avoid the condition of the previous embodiment construed that the bonding points may be disengaged while an external force is applied to the bonding wires, which are horizontally connected with the conductive pattern directly. Furthermore, all of the protrusions 87 can be supports for engaging against the cover body 78 while the cover body 78 is mounted on the substrate.

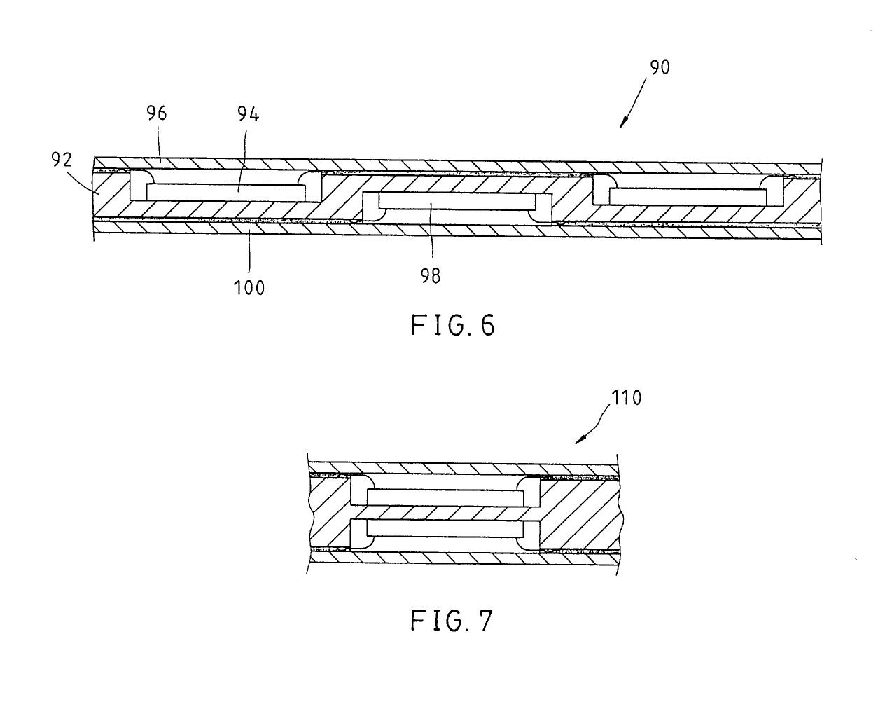

Referring to FIG. 6, the multi-chip module 90 of a third preferred embodiment of the present invention discloses that the chips can be received in both a topside and a downside of the substrate. The module 90 primarily comprises a substrate 92, a plurality of topside chips 94, a topside cover 96, a plurality of downside chips 98, and a downside cover 100. The topside cover is a planar plate, after the topside chips and the topside cover are installed, so that the substrate can be turned upside-down and the topside cover 96 is taken as a supporting member for installing and wire-bonding the downside chips 98, assembling the downside cover 100, and so on. Namely, in accordance with the technology disclosed by the present invention, it's very easy to assemble the chips on both the topside and the downside of the substrate such that the module 90 is provided with appropriate space for utilization.

A fourth preferred embodiment of the multi-chip module 110 of the present invention, as shown in FIG. 7, discloses the difference hereunder with the previous embodiment in that the topside receiving chamber and the downside receiving chamber are in corresponding position of back to back not side by side.

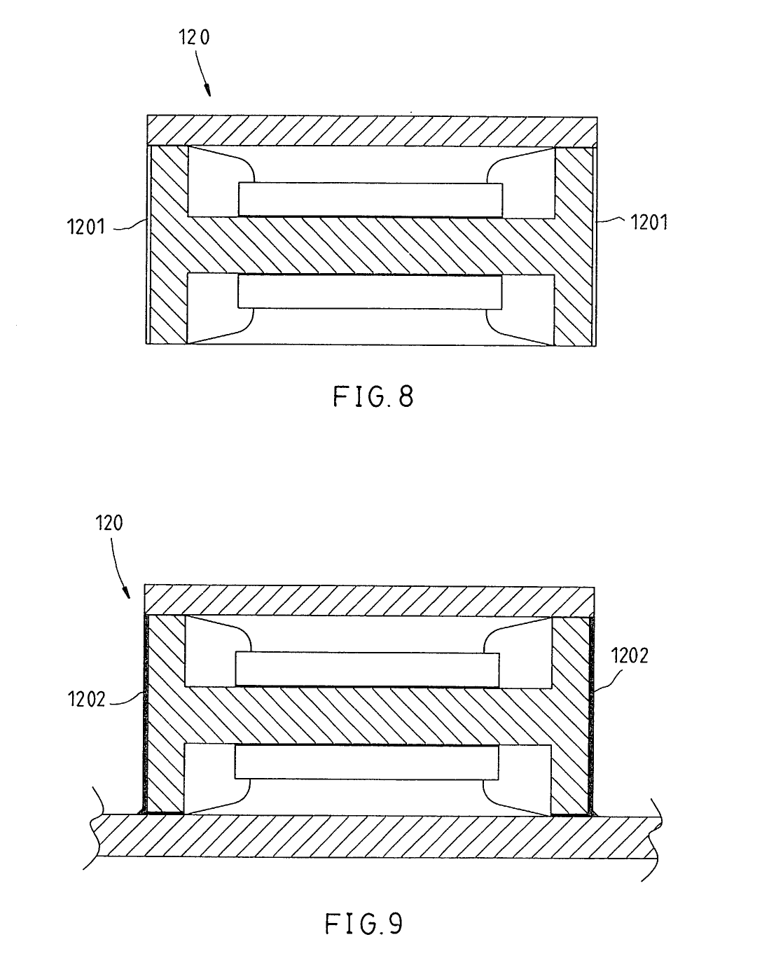

A fifth preferred embodiment of the multi-chip module 120 of the present invention, as shown in FIG. 8, discloses the difference hereunder with the previous embodiment. The cross-sectional view of the topside and the downside chips shows a modularized package. There are eyelets 1201 positioned on the periphery of the substrate and running through the top and the bottom surfaces thereof. While the modularized package 120 is installed on a circuit board, as shown in FIG. 9, tin solders 1202 are respectively filled into the eyelets 1201 to electrically connect the bonding wires of two chips on both the top and the bottom surfaces of the substrate and to electrically connect the two chips and an external circuit board.

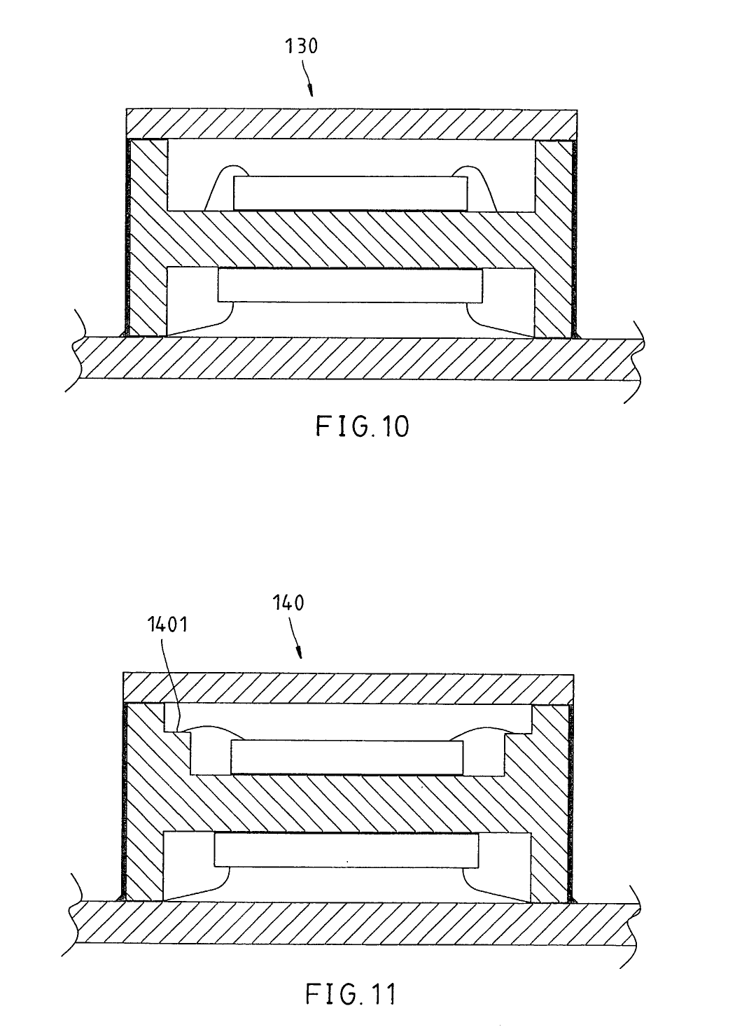

A sixth preferred embodiment of the multi-chip module 130 of the present invention, as shown in FIG. 10, discloses the difference hereunder with the previous embodiment. The chip having smaller size is disposed in the topside receiving chamber and electrically connected to the outside by the bonding wires. Although the package size of the topside receiving chamber is not reduced, the package size of the downside receiving chamber can also be reduced, and then the overall package size is still reduced.

A seventh preferred embodiment of the multi-chip module 140 of the present invention, as shown in FIG. 11, discloses the difference hereunder with the previous embodiment. The topside receiving chamber includes a laddered portion 1401, to which topside the metal bonding wires are electrically connected.

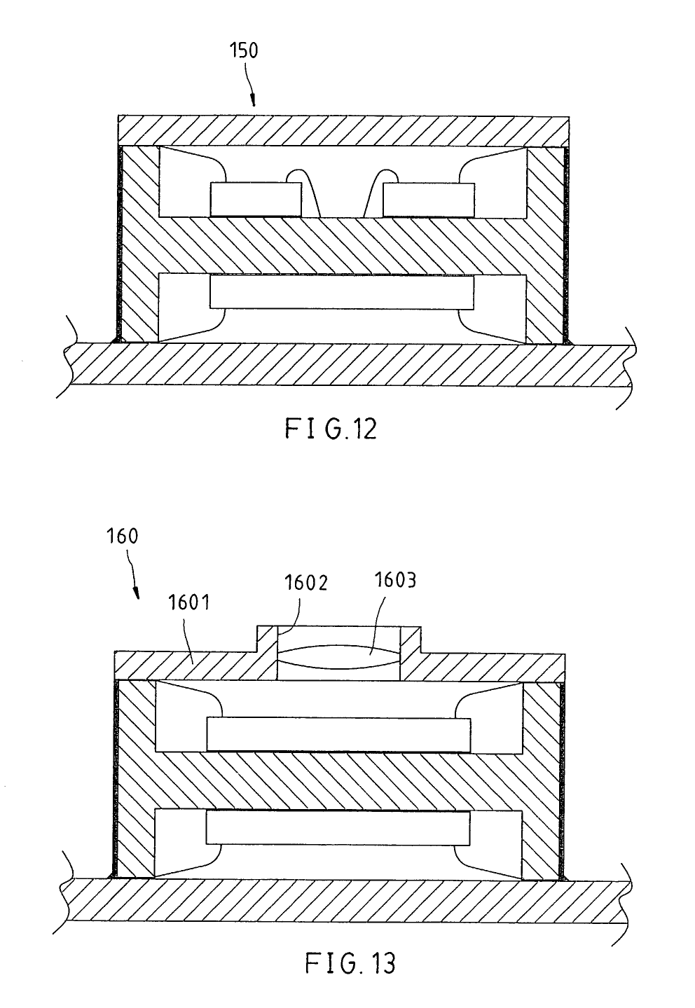

In fact, if the chip is small enough, two chips can be received in the receiving chamber, as the multi-chip module 150 of an eighth preferred embodiment shown in FIG. 12. In other words, either one of the chips received in the receiving chamber is connected with the top surface of the substrate by the bonding wires such that the package size can be reduced. Furthermore, the substrate or the cover body can be separately or simultaneously disposed with conductive patterns thereon.

A ninth preferred embodiment of the multi-chip module 160 of the present invention, as shown in FIG. 11, discloses the difference hereunder with the fifth preferred embodiment. The cover body 1601 has a hole 1602, in which a lens 1603 is installed to seal the hole. The light can be projected through the lens to the video chip of the topside receiving chamber.

What I claim is:

1. A multi-chip module comprising:
a substrate having a top surface, a bottom surface, and at least two receiving chambers recessed on said substrate;
at least two chips respectively fixedly received in said receiving chambers and electrically connected to said substrate by a plurality of bonding wires;
each said bonding wire having one end electrically connected to one of said chips, and the other end substantially horizontally electrically connected to said top surface of said substrate; and
a cover body fixedly mounted on said top surface of said substrate for covering each receiving chamber and isolating said chips from the outside.

2. The module as defined in claim 1, wherein said substrate comprises a predetermined conductive pattern disposed on said substrate.

3. The module as defined in claim 2, wherein said substrate comprises a plurality of protrusions on the top surface, each protrusion electrically connected with said conductive pattern and located at the periphery of an opening of said receiving chamber, wherein the other ends of the bonding wires are respectively electrically connected to said protrusions.

4. The module as defined in claim 3, wherein said protrusions are made of a metallic material.

5. The module as defined in claim 3, wherein said cover body has a top surface and a bottom surface, said bottom surface contacting bonding points where the bonding wires are bonded to said protrusions.

6. The module as defined in claim 1, wherein said cover body comprises a top surface and a bottom surface, said bottom surface contacting bonding points where the bonding wires are bonded to a conductive pattern on said substrate.

7. The module as defined in claim 1, wherein said cover body is made of a transparent material.

8. The module as defined in claim 1, wherein said substrate comprises an upside plate having a top surface, a bottom surface and at least a hole running through the top and the bottom surface, and a downside plate having a top surface and a bottom surface, said top surface of said downside plate attached to said bottom surface of said topside plate, whereby said hole and said downside plate form said receiving chamber.

9. The module as defined in claim 1 further comprising an adhesive, which is coated on the top surface of said substrate and adhesively fixedly connected with said cover body.

10. The module as defined in claim 9, wherein said adhesive covers over bonding points where the bonding wires are bonded to a conductive pattern of said substrate.

11. The module as defined in claim 9, wherein said adhesive is selected from the group consisting of silicone resin, epoxy resin, acrylic resin, and polyamide resin.

12. The module as defined in claim 1, wherein said cover body is fixedly mounted on said top surface of said substrate through screws.

13. The module as defined in claim 1, wherein said cover body is disposed with a predetermined conductive pattern thereon.

14. The module as defined in claim 1, wherein said receiving chamber is recessed inward from said top surface of said substrate.

15. The module as defined in claim 1, wherein one of said receiving chambers is recessed inward from the top surface of the substrate, and the other receiving chamber is recessed inward from the bottom surface of said substrate.
